(19) United States
(12) Patent Application Publication
(10) Pub. No.: US 2012/0049259 A1
(43) Pub. Date: Mar. 1, 2012

(54) ELECTROSTATIC DISCHARGE PROTECTION DEVICE

(75) Inventor: Kilho Kim, Icheon-si (KR)

(73) Assignee: BauaBTech

(21) Appl. No.: 13/189,646

(22) Filed: Jul. 25, 2011

(30) Foreign Application Priority Data
Aug. 31, 2010 (KR) 10-2010-0084528

(51) Int. Cl. H01L 27/06

(52) U.S. Cl. 257/300; 257/E27.011

(57) ABSTRACT

The present disclosure provides an ESD protection device. The ESD protection device includes a p-type well region and an n-type well region disposed to contact each other at one side thereof, an n-type drain region disposed on a contact surface between the p-type well region and the n-type well region, an n-type source region formed in the p-type well region and separated from the n-type drain region by a channel region, a gate electrode layer disposed above the channel region with a gate insulation layer interposed between the gate electrode layer and the channel to region, a p-type anode region disposed inside the n-type well region, a plurality of conductive layers for coupling resistance separated from each other over the p-type well region, a capacitor including an impurity region disposed inside the n-type well region and a capacitor electrode layer disposed above the n-type well region with an insulation layer interposed between the capacitor electrode layer and the n-type well region, a first wire connecting the n-type source region and one of the conductive layers to a cathode, the one of the conductive layers being disposed at one side of the device among the plurality of conductive layers for coupling resistance, a second wire connecting another conductive layer disposed at the other side of the device among the plurality of conductive layers for coupling resistance, the gate electrode layer, and the capacitor electrode layer to each other, and a third wire connecting the p-type anode region to an anode.

### BACKGROUND

1. Field of Technology

The present disclosure relates to electrostatic discharge protection devices and, more particularly, to an electrostatic discharge protection device of a gate coupled rectifier structure having high on-resistance.

2. Description

Generally, in fabrication of microchips, it is an essential aspect of chip design to provide a circuit for protecting a microchip from electrostatic discharge (ESD) stress. Typically, chip failure occurs when static electricity caused by contact between an external pad of a microchip and a charged human body or machine is discharged to a core circuit or when accumulated static electricity flows to the core circuit. Here, a device used to protect the core circuit from such chip failure is referred to as an electrostatic discharge protection device. The electrostatic discharge protection device is generally disposed between the external pad and the core circuit.

FIG. 1 is a graphical representation of fundamental requirements of an ESD protection device for a microchip. In FIG. 1, “A” indicates an operating range of the microchip, “B” indicates a safety margin, and “C” indicates a breakdown region. Referring to FIG. 1, the ESD protection device must prevent current flow therethrough upon application of voltage less than or equal to an operating voltage Vop during normal operation of the microchip. In order to satisfy this requirement, the avalanche breakdown voltage Vav and the triggering voltage Vtr of the ESD protection device at a triggering point Pt must be greater than the operating voltage Vop of the microchip during normal operation.

The ESD protection device must provide sufficient protection to a core circuit of the microchip when the microchip is subjected to electrostatic discharge stress. Thus, when electrostatic current flows to the microchip, it must be discharged to the outside through the ESD protection device before flowing into the core circuit. To satisfy this requirement, the triggering voltage Vtr of the ESD protection device must be sufficiently lower than the core circuit breakdown voltage Vccb of the microchip.

The ESD protection device must be prevented from abnormal operation resulting from a latch-up phenomenon. Generally, an efficient ESD protection device exhibits a resistance snapback characteristic wherein on-resistance of the ESD protection device is reduced after the device is triggered. Such a resistance snapback characteristic is exhibited as a voltage snapback phenomenon wherein the corresponding voltage is lowered, despite an increase in current flowing through the ESD protection device. Here, if the snapback phenomenon becomes too severe, the ESD protection device suffers the latch-up phenomenon which allows excess current to flow through the ESD protection device, thereby causing thermal breakdown of the microchip, even when the microchip is normally operated. To prevent the ESD protection device from performing abnormal operation resulting from the lath-up phenomenon, the snapback holding voltage Vh of the ESD protection device must be greater than the operating voltage of the microchip by a sufficient safety margin (Δ V). Alternatively, the triggering current Itr must be to sufficiently greater than a certain value, for example, 100 mA.

When the ESD protection device adopts a multi-finger structure, it is necessary for the respective fingers of the ESD protection device to uniformly operate. In other words, other fingers must also be triggered to cooperatively discharge ESD current before a certain finger is triggered and suffers thermal breakdown. To satisfy this requirement, the thermal breakdown voltage Vtb of the ESD protection device must be greater than or at least similar to the triggering voltage Vtr thereof. In addition, the ESD protection device must ensure sufficient immunity to electrostatic discharge current while having as small a size as possible.

Conventionally, a gate grounded N-type MOSFET (GGNMOS) electrostatic discharge protection device is commonly used. However, the triggering voltage Vtr of the GGNMOS device is substantially the same as the core circuit breakdown voltage Vccb of the core circuit to be protected by the GGNMOS device. Therefore, the GGNMOS device has difficulty providing fundamental prevention of electrostatic discharge current induced in the microchip from flowing into the core circuit and causing breakdown of the core circuit. Further, in order to handle a large amount of electrostatic discharge current, the GGNMOS device is excessively enlarged, causing the burden of increasing the overall size of the microchip.

Currently, a low voltage triggering N-type rectifier (LVTNR) electrostatic discharge protection device is suggested. The LVTNR ESD protection device can handle a large amount of electrostatic discharge current, as compared with the size of the device, through induction of rectifier operation of two parasitic bipolar junction (BJT) transistors. However, when the microchip is subjected to electrostatic discharge stress, the triggering voltage of the LVTNR ESD protection device is substantially similar to or greater than the core circuit breakdown voltage Vccb of the microchip. As a result, it is difficult for the LVTNR ESD protection device to provide fundamental prevention of electrostatic discharge current induced in the microchip from flowing into the core circuit and causing breakdown of the core circuit. Further, the snapback holding voltage Vh of the LVTNR ESD protection device is less than the operating voltage of the microchip, thereby providing a high possibility of causing the latch-up phenomenon due to the LVTNR device during normal operation of the microchip. Moreover, the thermal breakdown voltage Vtb of the LVTNR ESD protection device is much smaller than the triggering voltage Vtr thereof. As a result, when the multi-finger structure is adopted, the respective fingers can operate unevenly.

### SUMMARY

to Aspects of the present disclosure provide improved electrostatic discharge protection devices that can prevent a latch-up phenomenon by increasing on-resistance while maintaining advantages of an LVTNR device and enhancing efficiency of protecting a core circuit.

According to one aspect of the present disclosure, an electrostatic discharge (ESD) protection device includes: a p-type well region and an n-type well region disposed to contact each other at one side thereof; an n-type drain region disposed on a contact surface between the p-type well region and the n-type well region; an n-type source region formed in the p-type well region and separated from the n-type drain region by a channel region; a gate electrode layer disposed above the channel region with a gate insulation layer interposed between the gate electrode layer and the channel region; a p-type anode region disposed inside the n-type well region; a plurality of conductive layers for coupling resistance separated from each other over the p-type well region; a capacitor including an impurity region disposed inside the n-type well region and a capacitor electrode layer disposed above the n-type well region with an insulation layer interposed between the capacitor electrode layer and the n-type well region; a first wire connecting the n-type source region and one of the conductive layers to a cathode, the one of the conductive layers being disposed at one side of the device among the plurality of conductive layers for coupling resistance; a second wire connecting another conductive layer disposed at the other side of the device among the plurality of conductive layers for coupling resistance, the gate electrode layer, and the capacitor electrode layer to each other; and a third wire connecting the p-type anode region to an anode.

In one exemplary embodiment, the capacitor is disposed between the n-type drain region and the p-type anode region.

In another exemplary embodiment, the capacitor is disposed at one side of the p-type anode region opposite the n-type drain region.

In one exemplary embodiment, the ESD protection device may further include a p-n diode comprising a p-type anode junction region connected to the n-type source region and an n-type cathode junction region connected to the cathode. In this case, the ESD protection device may include a plurality of p-n diodes arranged in series.

In another exemplary embodiment, the ESD protection device includes a MOS transistor having a drain connected to the anode and a source connected to the cathode, a capacitor connected at one end thereof to the gate of the MOS transistor and at the other end thereof to the anode, and a resistor connected at one end thereof to the gate of the MOS transistor and the one end of the capacitor and at the other end thereof to the cathode.

In one exemplary embodiment, the ESD protection device further includes a diode disposed between the source of the MOS transistor and the cathode to perform forward operation.

### BRIEF DESCRIPTION OF THE DRAWINGS

The above and other aspects, features and advantages of the present disclosure will become apparent from the following description of exemplary embodiments given in conjunction with the accompanying drawings, in which:

FIG. 1 is a graphical representation of fundamental conditions for an ESD protection device;

FIG. 2 is a sectional view of an ESD protection device according to one exemplary embodiment of the present disclosure;

FIG. 3 is a circuit diagram of the ESD protection device of FIG. 2;

FIG. 4 is a graphical representation depicting electrical characteristics of the ESD protection device of FIG. 2;

FIG. 5 is a sectional view of an ESD protection device according to another exemplary embodiment of the present disclosure;

FIG. 6 is a circuit diagram of the ESD protection device of FIG. 5;

FIG. 7 is a sectional view of an ESD protection device according to a further exemplary embodiment of the present disclosure;

FIG. 8 is a circuit diagram of the ESD protection device of FIG. 7;

FIG. 9 is a sectional view of an ESD protection device according to yet another exemplary embodiment of the present disclosure;

FIG. 10 is a sectional view of an ESD protection device according to yet another exemplary embodiment of the present disclosure; and

FIG. 11 is a sectional view of an ESD protection device according to yet another embodiment of the present disclosure.

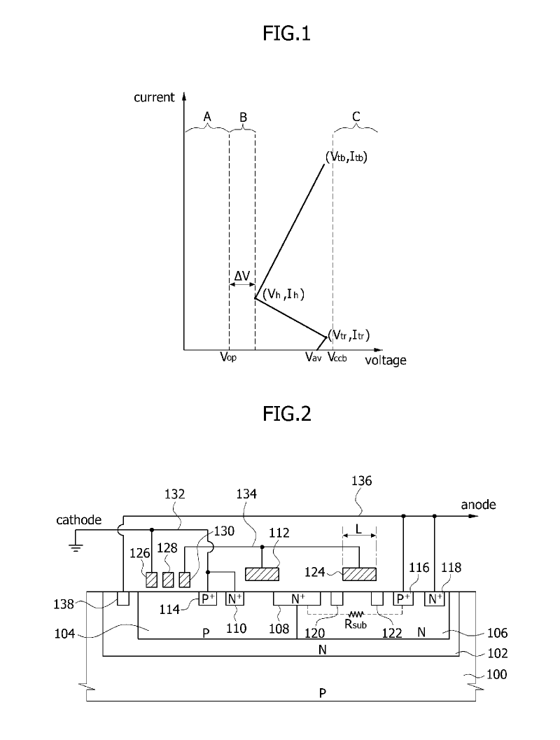

### DETAILED DESCRIPTION

Exemplary embodiments will now be described in detail with reference to the accompanying drawings.

FIG. 2 is a sectional view of an ESD protection device according to one exemplary embodiment of the present disclosure. Referring to FIG. 2, an n-type deep well region 102 is formed in an upper region of a p-type substrate 100. A p-type well region 104 and an n-type well region 106 are formed in an upper region of the n-type deep well region 102. The p-type well region 104 and the n-type well region 106 are disposed to contact each other at one side thereof. An n-type drain region 108 is disposed on a contact surface between the p-type well region 104 and the n-type well region 106. In other words, a partial left region of the n-type drain region 108 is located in an upper portion of the p-type well region 104 and a partial right region of the n-type drain region 108 is located in an upper portion of the n-type well region 106. An n-type source region 110 is disposed on the p-type well region 104 to be separated from the n-type drain region 108 by a channel region. A gate electrode 112 is disposed above the channel region. In one embodiment, the gate electrode 112 is formed of a polysilicon layer. Although not shown in the drawings, a gate insulation layer (not shown) is interposed between the gate electrode 112 and the channel region. A p-type cathode region 114 is formed on the p-type well region 104 to be separated a predetermined distance from the n-type source region 110.

In an upper region of the n-type well region 106, a p-type anode region 116 and an n-type anode compensation region 118 are disposed to be separated from each other. A first impurity region 120 and a second impurity region 122 are disposed between the n-type drain region 108 and the p-type anode region 116 to constitute a capacitor. Both the first impurity region 120 and the second impurity region 122 are an n-type conductive-type. A capacitor electrode layer 124 is disposed above the n-type well region 106 between the first and second impurity regions 120, 122, with a dielectric layer (not shown) interposed between the capacitor electrode layer 124 and the n-type well region 106. In one embodiment, the capacitor electrode layer 124 is formed of a polysilicon layer. The length L of the capacitor electrode layer 124 is determined in consideration of desired on-resistance. As the length L of the capacitor electrode layer 124 increases, that is, as the distance between the n-type drain region 108 and the p-type anode region 116 increases, on-resistance of a device increases.

A plurality of conductive layers 126, 128, 130 is disposed to be insulated from one another over a surface of the p-type well region 104 adjacent the p-type cathode region 114. Although this embodiment is illustrated as including three conductive layers, that is, a first conductive layer 126, a second conductive layer 128 and a third conductive layer 130, it is apparent that the present disclosure is not limited to this embodiment and may include more or less conductive layers than in the embodiment. In one embodiment, the first conductive layer 126, second conductive layer 128 and third conductive layer 130 are formed of a polysilicon layer. The first conductive layer 126 is disposed at one end of the protection device to be connected to the p-type cathode region 114 and the n-type source region 110 while being connected to a cathode connected to the ground through the first wire 132. The third conductive layer 130 is disposed at the other end of the protection device and is connected to the gate electrode layer 112 and the capacitor electrode layer 124 through the second wire 134. With this wiring structure, the first conductive layer 126, the second conductive layer 128 and the third conductive layer 130 are subjected to mutual coupling under predetermined conditions, for example, under a condition in which voltage is applied to both ends. An anode is connected to an impurity region 138, the p-type anode region 116 and the n-type anode compensation region 118, which are separated from the p-type well region 104, through a third wire 136. In some embodiments, the third wire 136 is not connected to the n-type anode compensation region 118.

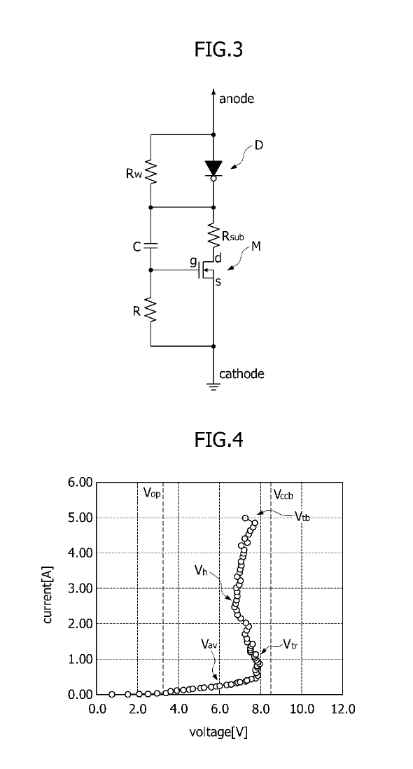

FIG. 3 is a circuit diagram of the ESD protection device of FIG. 2. Referring to FIGS. 2 and 3, an MOS transistor M is composed of the n-type drain region 108, the n-type source region 110 and the gate electrode layer 112, in which a source (s) is connected to the cathode and a drain (d) is connected to one end of a resistor R_{sub} in the n-type well region 106 between the n-type drain region 108 and the p-type anode region 116. Further, a gate (g) is connected to one end of a capacitor C while being connected to one end of a coupling resistor R. Here, the capacitor C is composed of the capacitor electrode layer 124, the first impurity region 120 and the second impurity region 122, and the coupling resistor R is composed of the first conductive layer 126, the second conductive layer 128 and the third conductive layer 130 separated from one another. Thus, the gate of the MOS transistor M is connected to the capacitor electrode layer 124 and the third conductive layer 130. The other end of the capacitor(C) is connected to the other end of the resistor R_{sub}, that is, one end of a resistor Rw in the n-type well region 106 to the anode. One end of each of the resistor R_{sub} and the resistor Rw is connected to an anode of a diode D. Here, the diode D is a p-n diode composed of the n-type well region 106 and the p-type anode region 116. The other end of the resistor Rw may be connected to the cathode or anode of the diode D. Alternatively, the other end of the resistor Rw may not be connected to the cathode or anode of the diode D (indicated by a dotted line in the drawings).

In such an ESD protection device, when electrostatic current flows between the anode and the cathode by connecting the cathode to ground and applying a positive electrostatic voltage to the anode, an NPN parasitic bipolar transistor and a PNP parasitic bipolar transistor are operated to discharge the electrostatic current. In particular, the NPN parasitic bipolar transistor and the PNP parasitic bipolar transistor are coupled to each other to operate as a rectifier through which the current smoothly flow. Here, the NPN parasitic bipolar transistor is a parasitic bipolar transistor composed of the n-type anode compensation region 118, the n-type well region 106 and an n-p-n structure of n-type drain region 108/p-type well region 104/n-type source region 110. Further, the PNP parasitic bipolar transistor means a parasitic bipolar transistor composed of the p-type cathode region 114 and a p-n-p structure of the p-type well region 104/n-type drain region 108, n-type well region 106/p-type anode region 116. When the NPN parasitic bipolar transistor and the PNP parasitic bipolar transistor perform rectifier operation, electrostatic discharge current spreads widely not only on the surface of the protection device but also in the vertical direction, so that a large amount of electrostatic discharge current can be discharged, as compared with the size of the device.

Particularly, the gate (g) of the MOS transistor M (gate electrode layer 112 of FIG. 2) is coupled to the anode via the capacitor electrode layer 124 and is connected to the cathode through the resistor R. Thus, an RC coupling structure is formed between the anode and the cathode, so that the MOS transistor M is operated at low voltage, thereby allowing quick operation of the NPN parasitic bipolar transistor at low voltage. Further, the capacitor C is located between the n-type drain region 108 and the p-type anode region 116, so that the distance and resistor R_{sub} between the n-type drain region 108 and the p-type anode region 116 increase, thereby providing an effect of increasing on-resistance between the anode and each of the impurity regions. As such, since the on-resistance between the anode and each of the impurity regions is high, the voltage between both ends of the ESD protection device is maintained at a constant level instead of being significantly reduced during actual rectifier operation. Furthermore, when the first impurity region 120 and the n-type anode compensation region 118 constituting the capacitor C are not connected to each other, the on-resistance is further increased.

FIG. 4 is a graphical representation depicting electrical characteristics of the ESD protection device of FIG. 2. As shown in FIG. 4, the ESD protection device according to this embodiment has the following characteristics. First, during normal operation of a microchip, the avalanche breakdown voltage Vav and the triggering voltage Vtr of the ESD protection device are greater than the operating voltage Vop of the microchip. Second, when the microchip is subjected to electrostatic discharge stress, the ESD protection device starts to operate at a voltage much lower than the core circuit breakdown voltage Vccb of the microchip. Thus, it is possible to provide fundamental prevention of electrostatic discharge current induced in the microchip from flowing into the core circuit and causing breakdown of the core circuit. Thirdly, the snapback holding voltage Vh of the ESD protection device is sufficiently greater than the operating voltage Vop of the microchip. Accordingly, the ESD protection device prevents a latch-up phenomenon during normal operation of the microchip. Fourthly, the thermal breakdown voltage Vtb of the ESD protection device is substantially similar to the triggering voltage Vtr thereof. Thus, when a multi-finger structure is adopted, the respective fingers may uniformly operate. Fifthly, the ESD protection device according to this embodiment exhibits an excellent level of current immunity per unit size with respect to electrostatic discharge current. For example, the ESD protection device according to this embodiment may process about two to three times more electrostatic discharge current than a GGNMOS device with the same layout area as that of the ESD protection device.

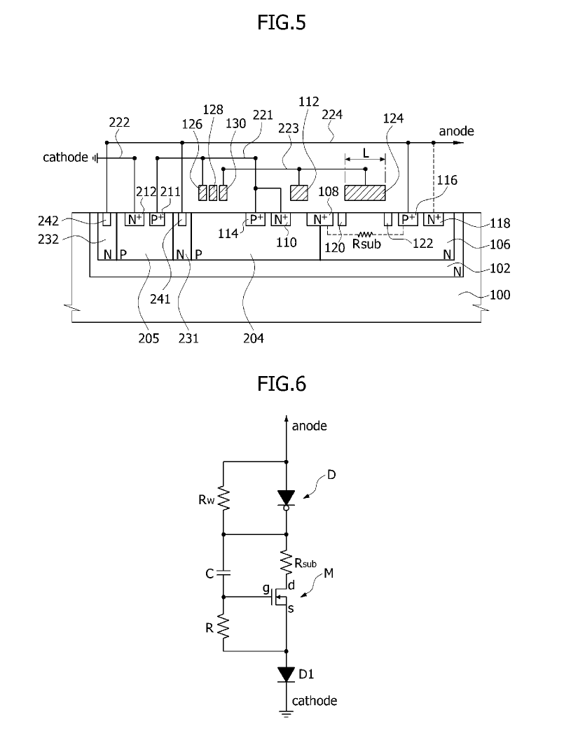

FIG. 5 is a sectional view of an ESD protection device according to another exemplary embodiment of the present disclosure, and FIG. 6 is a circuit diagram of the ESD protection device of FIG. 6. In FIGS. 5 and 6, the same elements are indicated by the same reference numerals as those of FIGS. 2 and 3, and descriptions thereof will thus be omitted. Referring to FIGS. 5 and 6, the ESD protection device according to this embodiment is distinguished from the ESD protection device of FIG. 2 in that a PN diode D1 is located between a cathode and a MOS transistor M composed of an n-type drain region 108, an n-type source region 110 and a gate electrode layer 112. Specifically, a p-type well region 205 is disposed adjacent a p-type well region 204, one side of which contacts an n-type well region 106, and a p-type anode junction region 211 and an n-type cathode junction region 212 constituting the PN diode D1 are formed in the p-type well region 205. N-type well regions 231, 232 are disposed at opposite sides of the p-type well region 205 with the PN diode D1 formed therein, and are respectively provided with impurity regions 241, 242 for wire connection.

In this state, the p-type anode junction region 211 of the PN diode D1, a first conductive layer 126 of a coupling resistor R, a p-type cathode region 114, and the n-type source region 110 are connected to one another through a first wire 221. The n-type cathode junction region 212 of the PN diode D1 is connected to the cathode through a second wire 222. In this connection structure, the anode of the PN diode D1 is connected to both a source (s) of the MOS transistor M and one end of the coupling resistor R. The third conductive layer 130 of the coupling resistor R, the gate electrode layer 112, and the capacitor electrode layer 124 are connected to each other through a third wire 223. Further, the impurity regions 241, 242, the p-type anode region 116 and the n-type anode compensation region 118 are connected to the anode through a fourth wire 224. Here, the n-type anode compensation region 118 may not be connected to the fourth wire 224 (indicated by a dotted line in the drawing).

The ESD protection device of this embodiment further increases on-resistance by the PN diode D1 for forward operation serially connected to the MOS transistor M. Upon application of electrostatic discharge current, the PN diode D1 performs forward operation together with rectifier operation of the parasitic bipolar transistors, thereby causing voltage increase proportional to the amount of current passing therethrough by the diode forward operation in which the ESD protection device does not exhibit snapback characteristics, instead of the rectifier operation in which the ESD protection device does not exhibit the snapback characteristics. Accordingly, it is possible for the ESD protection device to further increase on-resistance and the snapback holding voltage Vh.

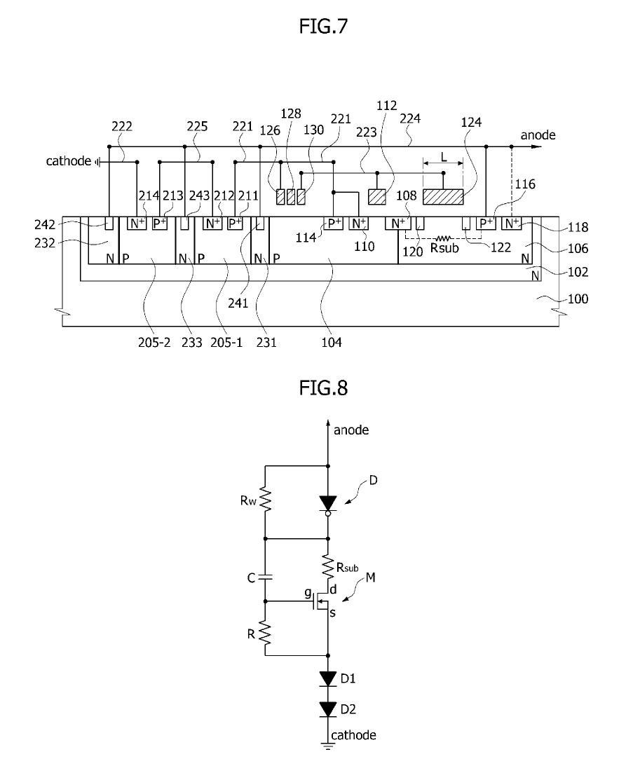

FIG. 7 is a sectional view of an ESD protection device according to a further exemplary embodiment of the present disclosure, and FIG. 8 is a circuit diagram of the ESD protection device of FIG. 7. In FIGS. 7 and 8, the same elements are indicated by the same reference numerals as those of FIGS. 5 and 6, and descriptions thereof will thus be omitted. Referring to FIGS. 7 and 8, the ESD protection device according to this embodiment is distinguished from the ESD protection device shown in FIG. 5 in that the ESD protection device of this embodiment includes two PN diodes. Specifically, a first PN diode D1 composed of a first p-type anode junction region 211 and a first n-type cathode junction region 212 is disposed in a p-type well region 205-1, and a second PN diode D2 composed of a second p-type anode junction region 213 and a second n-type cathode junction region 214 is disposed in a p-type well region 205-2. An n-type well region 233 is disposed between the p-type well region 205-1 having the first PN diode D1 therein and the p-type well region 205-1 having the second PN diode D2 therein, and includes an impurity region 243 for wire connection.

To allow forward operation of the first and second PN diodes D1 and D2, a cathode is connected to the second n-type cathode junction region 214 of the second PN diode D2 via a second wire 222, and the first p-type anode junction region 211 of the first PN diode D1 is connected to a first conductive layer 126 of a coupling resistor R, a p-type anode region 114 and an n-type source region 110 via a first wire 221. Further, the first n-type cathode junction region 212 of the first PN diode D1 is connected to the second p-type anode junction region 213 of the second PN diode D2 via a fifth wire 225. In the ESD protection device according to this embodiment, the two PN diodes D1, D2 are arranged to be connected in series between the MOS transistor M and the cathode to perform forward operation, so that the ESD protection device exhibits higher on-resistance and snapback holding voltage Vh than the ESD protection device illustrated with reference to FIG. 5.

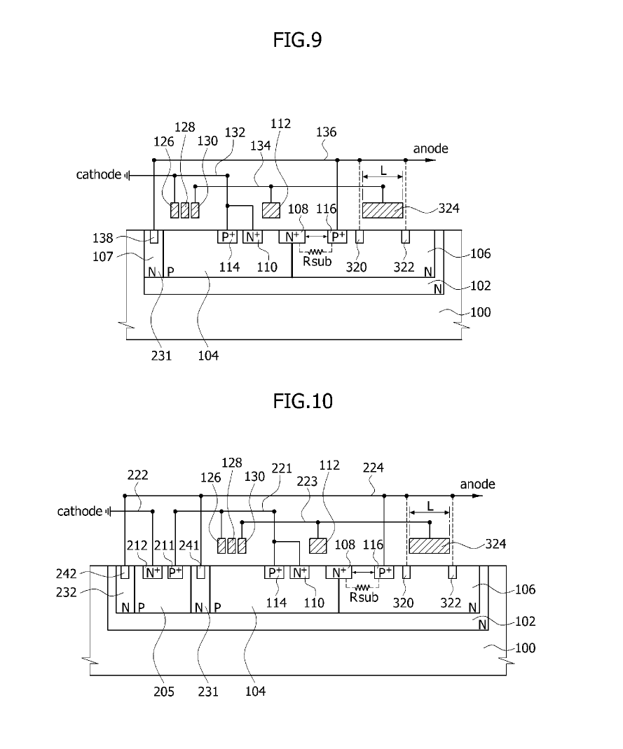

FIG. 9 is a sectional view of an ESD protection device according to yet another exemplary embodiment of the present disclosure. In FIG. 9, the same elements are indicated by the same reference numerals as those of FIG. 5, and descriptions thereof will thus be omitted. For reference, a circuit diagram of the ESD protection device shown in FIG. 9 is the same as that shown in FIG. 3. Referring to FIG. 9, in the ESD protection device according to this embodiment, a p-type anode region 116 is disposed adjacent an n-type drain region 108, and a first impurity region 320, a second impurity region 322 and a capacitor electrode layer 324 are disposed to constitute a capacitor C outside the p-type anode region 116. Therefore, when the capacitor electrode layer 324 is formed to a sufficiently long length L in order to provide sufficient on-resistance, the resistance R_{sub} does not increase due to increase of the length L of the capacitor electrode layer 324. Upon rectifier operation of the device, since the on-resistance increases proportional not only to the length L of the capacitor electrode layer 324 but also to the resistance R_{sub}, the on-resistance excessively increases when the length L and the resistance R_{sub} of the capacitor electrode layer 324 increase at the same time, thereby making it difficult to properly handle the electrostatic discharge current. In the ESD protection device according to this embodiment, however, since the length L of the capacitor electrode layer 324 may be adjusted as needed without increasing the resistance R_{sub}, it is possible to control the on-resistance of the device to a desired level.

FIG. 10 is a sectional view of an ESD protection device according to yet another exemplary embodiment of the present disclosure. In FIG. 10, the same elements are indicated by the same reference numerals as those of FIGS. 5 and 9, and descriptions thereof will thus be omitted. A circuit diagram of the ESD protection device shown in FIG. 10 is the same as that shown in FIG. 6. As described with reference to FIG. 9, in the ESD protection device according to this embodiment, a first impurity region 320, a second impurity region 322 and a capacitor electrode layer 324 are disposed to constitute a capacitor outside the p-type anode region 116 to increase the length L of a capacitor electrode layer 324 without increasing the resistance R_{sub}. Further, as described with reference to FIG. 5, a PN diode for forward operation is disposed between the MOS transistor and the cathode, so that the ESD protection device exhibits high on-resistance and snapback holding voltage Vh.

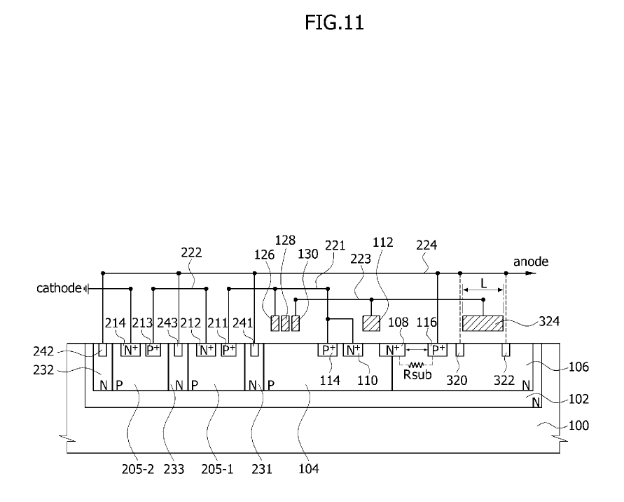

FIG. 11 is a sectional view of an ESD protection device according to yet another exemplary embodiment of the present disclosure. In FIG. 11, the same elements are indicated by the same reference numerals as those of FIGS. 7 and 10, and descriptions thereof will thus be omitted. For reference, a circuit diagram of the ESD protection device shown in FIG. 11 is the same as that shown in FIG. 8. As described with reference to FIG. 9, in the ESD protection device according to this embodiment, a first impurity region 320, a second impurity region 322 and a capacitor electrode layer 324 are disposed to constitute a capacitor outside the p-type anode region 116 to increase the length L of a capacitor electrode layer 324 without increasing the resistance R_{sub}. Further, as described with reference to FIG. 7, first and second PN diodes D1, D2 for forward operation are disposed between the MOS transistor and the cathode, so that the ESD protection device exhibits high on-resistance and snapback holding voltage Vh.

As such, according to the embodiments, the ESD protection devices can prevent a latch-up phenomenon by increasing on-resistance while maintaining advantages of an LVTNR device and enhancing efficiency of protecting a core circuit.

Although some embodiments have been provided to illustrate the present disclosure, it should be understood that these embodiments are given by way of illustration only, and that various modifications, variations, and alternations can be made without departing from the spirit and scope of the present disclosure. The scope of the present disclosure should be limited only by the accompanying claims and equivalents thereof.

What is claimed is:

1. An electrostatic discharge (ESD) protection device, comprising:
a p-type well region and an n-type well region disposed to contact each other at one side thereof;
an n-type drain region disposed on a contact surface between the p-type well region and the n-type well region;
an n-type source region formed in the p-type well region and separated from the n-type drain region by a channel region;
a gate electrode layer disposed above the channel region with a gate insulation layer interposed between the gate electrode layer and the channel region;
a p-type anode region disposed inside the n-type well region;
a plurality of conductive layers for coupling resistance separated from each other over the p-type well region;
a capacitor including an impurity region disposed inside the n-type well region and a capacitor electrode layer disposed above the n-type well region with an insulation layer interposed between the capacitor electrode layer and the n-type well region;
a first wire connecting the n-type source region and one of the conductive layers to a cathode, the one of the conductive layers being disposed at one side of the device among the plurality of conductive layers for coupling resistance;
a second wire connecting another conductive layer disposed at the other side of the device among the plurality of conductive layers for coupling resistance, the gate electrode layer, and the capacitor electrode layer to each other; and
a third wire connecting the p-type anode region to an anode.

2. The ESD protection device according to claim 1, wherein the capacitor is disposed between the n-type drain region and the p-type anode region.

3. The ESD protection device according to claim 1, wherein the capacitor is disposed at one side of the p-type anode region opposite the n-type drain region.

4. The ESD protection device according to claim 1, further comprising:
a p-n diode comprising a p-type anode junction region connected to the n-type source region and an n-type cathode junction region connected to the cathode.

5. The ESD protection device according to claim 4, wherein a plurality of the p-n diodes is arranged in series.

6. An electrostatic discharge (ESD) protection device, comprising:
a MOS transistor having a drain connected to an anode and a source connected to a cathode;
a capacitor connected at one end thereof to the gate of the MOS transistor and connected at the other end thereof to the anode; and
a resistor connected at one end thereof to the gate of the MOS transistor and the one end of the capacitor, and connected at the other end thereof to the cathode.

7. The ESD protection device according to claim 6, further comprising: a diode disposed between the source of the MOS transistor and the cathode to perform forward operation.
